(19) United States
(12) Patent Application Publication
(10) Pub. No.: US 2023/0265337 A1
(43) Pub. Date: Aug. 24, 2023

(54) CONVERTER ELEMENT, METHOD FOR PRODUCING A CONVERTER ELEMENT AND RADIATION EMITTING DEVICE

(71) Applicant: ams-OSRAM International GmbH, Regensburg (DE)

(72) Inventors: Florencio GARCIA, North Hampton, NH (US); Alan PIQUETTE, Kensington, NH (US); Gertrud KRÄUTER, Regensburg (DE)

(21) Appl. No.: 17/677,898

(22) Filed: Feb. 22, 2022

(51) Int. Cl. C09K 11/02; H01L 33/50; C09K 11/77; C08G 77/04; C08K 3/22; C08K 3/28

(52) U.S. Cl. CPC C09K 11/02; H01L 33/504; C09K 11/7774; C09K 11/77348; C08G 77/04; C08K 3/22; C08K 3/28; C08G 77/70

(57) ABSTRACT

A converter element is provided, comprising a first conversion region comprising a first phosphor, a second conversion region comprising a second phosphor, wherein the first phosphor has upon excitation a faster radiation decay lifetime than the second phosphor, wherein at least one of the first and second phosphor is embedded in a matrix material, wherein the matrix material comprises a three-dimensionally crosslinked polysiloxane having an organic content of less than 40 wt %. Further, a method for producing a converter element and a radiation emitting device are provided.

A converter element, a method for producing a converter element and a radiation emitting device are disclosed.

Embodiments provide a converter element with improved performance. Further embodiments provide a method for producing a converter element with improved performance. Further embodiments provide a radiation emitting device with improved performance.

According to at least one embodiment a converter element is provided.

A converter element is to be understood as an element that is able to absorb electromagnetic radiation of a first wavelength range (also called primary radiation) and emit electromagnetic radiation of a second wavelength range (also called secondary radiation). The absorbed radiation has, in particular, a wavelength maximum that is different from, for example smaller than, the wavelength maximum of the emitted radiation. Such a process is called wavelength conversion. In particular, scattering or absorption alone is not meant with the term “wavelength conversion” at present. For example, the wavelength maximum of the absorbed radiation is in the UV or blue spectral range, i. e. at wavelengths in a range of 400 nm to 500 nm, and the wavelength maximum of the emitted radiation is in the yellow, green or red spectral range, i.e. at longer wavelengths than the absorbed radiation. Such a process is called down-conversion.

According to at least one embodiment the converter element comprises a first conversion region comprising a first phosphor and a second conversion region comprising a second phosphor. Thus, the first conversion region comprises the first phosphor or consists thereof, and the second conversion region comprises the second phosphor or consists thereof. In particular, the first phosphor is different from the second phosphor.

A phosphor is to be understood as the material in the converter element that is responsible for the converting properties, i.e. the wavelength conversion, as explained above. In other words, the phosphor absorbs electromagnetic radiation, which is, for example, emitted by a light emitting diode (LED), converts it by a molecular and/or an atomar mechanism, and re-emits it at, for example, longer wavelengths. The phosphor has, thus, photoluminescent properties.

The first and the second conversion regions are areas of the converter element that are distinguishable from each other, for example, by their materials. Due to the—at least partially—different composition of the first and the second conversion region the converter element may be called a hybrid converter element. The first and the second conversion region can have conversion characteristics that are different from each other. In particular, the first conversion region can convert the primary radiation into radiation with a emission maximum that is different from the emission maximum of the radiation emitted by the second conversion region. Both converted radiations contribute to the secondary radiation emitted by the converter element.

According to at least one embodiment the first phosphor has upon excitation a faster radiation decay lifetime than the second phosphor. “Upon excitation” means here, the absorption of electromagnetic radiation, i.e. the absorption of photons, whereby electrons in the phosphor are excited to a higher energy level. The radiation decay lifetime is the time span in which the electrons, after excitation, return to a lower energy level while radiating other photons.

While there are many different phosphor materials, for LED applications there are two rare earth dopants widely used in phosphors of converter elements: Cerium (Ce) and Europium (Eu). Ce-doped phosphors typically have a broad emission band in the yellow-green region while Eu-based phosphors can be engineered to emit almost anywhere in the visible spectral range. However, radiation decay lifetimes of Eu-doped phosphors are typically one or two orders of magnitude slower than radiation decay lifetimes of Ce-doped phosphors.

According to at least one embodiment at least one of the first and second phosphor is embedded in a matrix material, wherein the matrix material comprises a three-dimensionally crosslinked polysiloxane having an organic content of less than 40 wt %, in particular less than 20 wt %. Here and in the following the term “matrix material” means the three-dimensionally crosslinked polysiloxane having an organic content of less than 40 wt %, optionally comprising any additives.

So, both or only one of the first and second conversion regions comprise the matrix material and the respective phosphor, i.e. the first phosphor or the second phosphor, embedded therein or consist thereof. “Embedded” means here, that the matrix material encapsulates phosphor particles, for example particles of a phosphor powder, of the first phosphor and/or of the second phosphor. The phosphor particles can also be a blend of different phosphors. That is, the first phosphor can be a blend of different first phosphors and/or the second phosphor can be a blend of different second phosphors. “Organic content” means here, organic residues in the three-dimensionally polysiloxane network that would be eliminated when heating it. Thus, the less organic content the more thermally stable is the matrix material.

According to at least one embodiment a converter element is provided, the converter element comprising:
a first conversion region comprising a first phosphor,
a second conversion region comprising a second phosphor,
wherein the first phosphor has upon excitation a faster radiation decay lifetime than the second phosphor,
wherein at least one of the first and second phosphor is embedded in a matrix material,
wherein the matrix material comprises a three-dimensionally crosslinked polysiloxane having an organic content of less than 40 wt %.

Such a converter element has a design enabling reducing or eliminating losses due to saturation and, additionally or alternatively, comprises a matrix material that improves thermal stability and thermal conductivity of the converter element.

In a radiation emitting device, long radiation decay lifetimes of phosphors in the conversion element increase the probability of absorbing multiple photons from an excitation source, for example an LED, before radiative decay has occurred. In this case, the excited electrons can non-radiatively decay through a variety of mechanisms that decrease the overall external quantum efficiency of the device and contribute to the generation of heat that further decreases the efficiency and can accelerate the degradation of components in the radiation emitting device. This physical process is often referred to as saturation.

Due to the implementation of the converter element with a first and a second conversion region having a first and a second phosphor wherein the first phosphor has upon excitation a faster radiation decay lifetime than the second phosphor, it is principally possible to apply such a converter element on an excitation source, for example a LED, such that the first conversion region, and thus, the first phosphor having a faster radiation decay lifetime, is closer to the excitation source. Then, the first phosphor can take most of the primary radiation and help to disperse heat through the excitation source. The second conversion region comprising the second phosphor with the slower radiation decay lifetime, i.e. the phosphor that is more sensitive to saturation, receives then only the photons that have not been previously absorbed by the first phosphor. This reduces the amount of saturation on the second phosphor contained in the second conversion region while still allowing the possibility of combining multiple phosphors in the converter element and therefore engineer a desired emission spectrum in dependence of a specific application. Therefore, with the converter element described here low saturation losses and a spectral flexibility by combining multiple phosphors can be provided. Thus, even phosphors with a slow radiation decay lifetime, such as Eu-doped phosphors, can be used with high performance in mid to high power applications where the flux of the excitating photons would be high enough to lead to saturation, such as among others, automotive headlamps, projection, stage lighting, and flash applications.

Additionally, the matrix material comprising a three-dimensionally crosslinked polysiloxane and having an organic content of less than 40 wt %, in particular less than 20 wt %, improves the thermal stability of the converter element.

Traditional silicone materials that are normally used in radiation emitting devices like LEDs are most often comprised of primarily D-units as functional monomeric unit in the precursor material of the silicone. As can be seen from table 1 showing the monomeric units of precursors of silicones (or

TABLE 1

| Monouser | Designation |
|---|---|
| 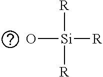 | M |
| 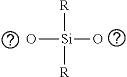 | D |
| 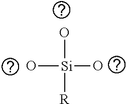 | T |
| 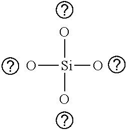 | Q |

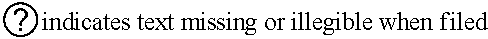

siloxanes) and their respective abbreviations, in a D-unit each silicon atom is bonded to two organic groups R. R can be chosen from alkyl, aryl, or any functional group where the bonding atom is a carbon atom. For example, R is methyl. Once cured, silicones based on D-units have a relatively high organic content, not only from the R-groups bonded to the silicon atoms, but also from the cross-linking groups that are present.

The matrix material as described here, i.e. the three-dimensionally crosslinked polysiloxane, is primarily based on T-units and contains primarily siloxane bonds. T-unit siloxanes only have one organic group R per silicon atom, and the cross-linking is often based on hydrolysis and condensation which serves to further remove organic content in the cured, i.e. crosslinked, state compared to an uncured state.

Thus, while conventional silicones based on D-units have an organic content of about 60 wt %, a three-dimensionally crosslinked polysiloxane as described here, has an organic content of less than 40 wt %, in particular less than 20 wt %. The large difference in organic content leads to an improved thermal stability of the three-dimensionally crosslinked polysiloxane primarily based on T-units which makes the converter element suitable for use in high temperature applications, i.e. even at temperatures of 150° C. or more, the converter element comprising the matrix material does not or insignificantly show degradation under such conditions.

According to at least one embodiment the three-dimensionally crosslinked polysiloxane comprises repeating units of the formula [RSiO_{3/2}]ₓ[R₂SiO]_{y}[R₃SiO_{1/2}]_{z} wherein x+y+z=1, 0<x≤1, 0≤y<1, 0≤z<1; preferably 0.6≤x≤1, 0≤y<0.4, 0≤z<0.4, and each R is independently from each other chosen from an organic functional group having a carbon atom as bonding atom, in particular, R is independently from each other chosen from alkyl and aryl, for example R is independently from each other chosen from methyl and phenyl. Here, x, y, and z indicate the relative proportions of the three types of groups, T-, D- and M-units, respectively. In particular, the relative proportion of T-units is higher than the relative proportions of D- and M-units. For example, the three-dimensionally crosslinked polysiloxane comprises more than 60% T-units, in particular 100% T-units. The formula can also be described by bond-line formula (I)

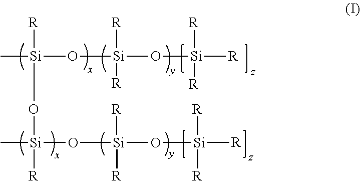

In formula (I) the curved brackets indicate repeating units, while the square brackets do not necessarily indicate repeating units.

According to at least one embodiment R is methyl and y=z=0. In this case the three-dimensionally crosslinked polysiloxane is based only on T-units and comprises a repeating unit of the formula (CH₃)SiO_{3/2}, that can also be described by the bond-line formula (Ia)

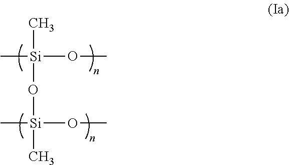

Here, n indicates that the repeat units extend to form a highly crosslinked, three-dimensional network of siloxane bonds. This depiction is simplified to highlight the fundamental repeat unit and how one chain can crosslink with another.

According to at least one embodiment the first conversion region comprises the first phosphor being embedded in the three-dimensionally crosslinked polysiloxane and/or the second conversion region comprises the second phosphor being embedded in the three-dimensionally crosslinked polysiloxane, wherein the amount of the first phosphor and/or the second phosphor in the three-dimensionally crosslinked polysiloxane is in a range of 8 vol % to 74 vol % inclusive, in particular in a range of 15 vol % to 55 vol % inclusive. The exact amount of phosphor in the matrix material in the respective conversion region depends on the application of the converter element, the desired colour point, and characteristics of the applied phosphors. For example, an application requiring a saturated red colour will need much more phosphor than an application requiring a bluish-white colour, when the primary radiation is in the blue or UV range. Likewise, an application requiring a thick converter element will require a lower phosphor concentration than a thin converter element at the same colour point. The phosphor concentration also depends on the activator, i.e. dopant concentration in the phosphor, as some phosphors absorb more primary radiation than others.

According to at least one embodiment one of the first and the second phosphor is embedded in the matrix material and the other one of the first and the second phosphor is one of a ceramic phosphor, a single crystal phosphor and a phosphor-in-glass, for example a phosphor in SiO₂. Thus, an inorganic conversion region comprising or consisting of a ceramic phosphor, a single crystal phosphor or a phosphor-in-glass, in particular a ceramic phosphor, can be combined with a conversion region comprising or consisting of the matrix material and a phosphor embedded therein. Thus, phosphors that are available in the form of ceramics, single crystals or phosphor-in-glass can be combined with phosphors that need to be embedded in matrix materials, providing various possibilities of combinations of phosphors.

A ceramic phosphor, a single crystal phosphor and a phosphor-in-glass have a good thermal conductivity and allow dispersing the heat generated during the conversion process. Additionally, these materials allow a high filling ratio of phosphor vs. air, in case of the ceramic phosphor and the single crystal phosphor a filling ratio of up to 100%. Such a high filling ratio allows for higher absorption of primary radiation and lower scattering which improves the efficiency and enables a lower thickness of the converter element than would be needed otherwise.

According to at least one embodiment the second phosphor is embedded in the matrix material and the first phosphor is one of a ceramic phosphor, a single crystal phosphor and a phosphor-in-glass. Thus, the converter element comprises an inorganic first conversion region comprising a or consisting of a first phosphor having a faster radiation decay lifetime, and a second conversion region comprising or consisting of a second phosphor embedded in the matrix material, the second phosphor having a slower radiation decay lifetime.

According to at least one embodiment the phosphor being a ceramic, single crystal phosphor or phosphor-in-glass, for example but not limited to the first phosphor, is chosen from a group consisting of (RE₁₋ₓCeₓ)₃(Al_{1-y}A′_{y})₅O₁₂ with 0<x≤0.1 and 0≤y≤1, (RE₁₋ₓCeₓ)₃(Al_{5-2y}Mg_{y}Si_{y})O₁₂ with 0<x≤0.1 and 0≤y≤2, (RE₁₋ₓCeₓ)₃Al_{5-y}Si_{y}O_{12-y}N_{y} with 0<x≤0.1 and 0≤y≤0.5, (RE₁₋ₓCeₓ)₂CaMg₂Si₃O₁₂:Ce³⁺ with 0<x≤0.1, (AE₁₋ₓEuₓ)₂Si₅N₈ with 0<x≤0.1, (AE₁₋ₓEuₓ)AlSiN₃ with 0<x≤0.1, (AE₁₋ₓEuₓ)₂Al₂Si₂N₆ with 0<x≤0.1, (Sr₁₋ₓEuₓ)LiAl₃N₄ with 0<x≤0.1, (AE₁₋ₓEuₓ)₃Ga₃N₅ with 0<x≤0.1, (AE₁₋ₓEuₓ)Si₂O₂N₂ with 0<x≤0.1, (AEₓEu_{y})Si_{12-2x-3y}U_{y}N_{16-y} with 0.2≤x≤2.2 and 0<y≤0.1, (AE₁₋ₓEUₓ)₂SiO₄ with 0<x≤0.1, (AE₁₋ₓEUₓ)₃SiO₅ with 0<x≤0.1, K₂(Si_{1-x-y}Ti_{y}Mnₓ)F₆ with 0<x≤0.2 and 0<y≤1-x, (AE₁₋ₓEuₓ)₅(PO₄)₃Cl with 0<x≤0.2, (AE₁₋ₓEUₓ)Al₁₀O₁₇ with 0<x≤0.2, wherein RE is one or more of Y, Lu, Tb and Gd, AE is one or more of Mg, Ca, Sr, Ba, A′ is one or more of Sc and Ga, Eu (II)-doped β-SiAlON and combinations thereof. Other luminescent materials having dopants like Cr³⁺, Ni²⁺, Co²⁺, Cu²⁺ or other optically active dopants are possible materials as well. These phosphors are able to absorb in the near-UV to blue region of the electromagnetic spectrum and emit in the visible region of the electromagnetic spectrum. The phosphor can be chosen depending on the desired colour point, and other spectral properties.

According to at least one embodiment the phosphor being embedded in the matrix material, for example but not limited to the second phosphor, is chosen from any of the materials listed for the phosphor being a ceramic, single crystal or phosphor-in-glass, or any combination thereof. Further possible phosphors that can be embedded in the matrix material are quantum dots. The phosphor being embedded in the matrix material can be a phosphor powder or a blend of phosphor powders and can be chosen depending on the desired colour point and other spectral properties.

Any combination of first and second phosphor can be chosen as long as the first phosphor has a faster radiation decay lifetime than the second phosphor.

According to at least one embodiment the converter element comprises a first conversion region comprising or consisting of a first phosphor being a Ce-doped ceramic phosphor and a second conversion region comprising or consisting of the second phosphor being an Eu-doped phosphor and the matrix material. For example, the first phosphor is Ce:LuAG and the second phosphor is Eu:β-SiAlON.

According to at least one embodiment the first conversion region and/or the second conversion region comprises a first phase being free of phosphor and a second phase comprising the phosphor. Thus, in case of a conversion region, for example the second conversion region, comprising a phosphor, for example the second phosphor, embedded in the matrix material the concentration of the phosphor can have a gradient. In case of a conversion region, for example the first conversion region, being an inorganic conversion region a first non-luminescent phase and a second luminescent phase can be sintered into a dense composite material body.

According to at least one embodiment in an inorganic conversion region, for example the first conversion region, the first non-luminescent phase comprises a material chosen from silica, alumina, an oxide garnet, a spinel, and a silicate. Any other inorganic material that has a relatively high thermal conductivity but low absorption in the visible region of the spectrum is applicable, too. The second phase comprises in this case the phosphor, for example the first phosphor, being a ceramic, a single crystal or a phosphor-in-glass.

According to at least one embodiment the first conversion region and the second conversion region comprise a common boundary or the first conversion region and the second conversion region are glued together. Thus, depending on the method of producing the converter element, the first conversion region and the second conversion region are in direct mechanical contact to each other, or they are glued together with a glue being chosen from, for example, silicone, filled silicone, siloxane, filled siloxane, and the matrix material, i.e. the three-dimensionally crosslinked polysiloxane as described here. The glue can form a bonding region, for example a bonding layer, between the first conversion region and the second conversion region.

According to at least one embodiment the first conversion region is a first conversion layer and the second conversion region is a second conversion layer, wherein the first and second conversion layers are stacked. The layers can be in direct mechanical contact to each other or they can be glued together. For example, the first conversion layer is an inorganic conversion layer. In this case, the converter element can be applied to a radiation emitting source, for example, an semiconductor chip, with the first conversion layer facing the radiation emitting source, so that the first phosphor with the faster radiation decay lifetime is closer to the radiation emitting source, and saturation through the second phosphor is reduced and the thermal management is optimized. For example, the first phosphor can be made of Ce-doped materials that can sustain higher fluxes and also improves dissipation of heat.

According to at least one embodiment the first conversion region is a first conversion layer comprising at least one recess, wherein the second conversion region is arranged in the at least one recess. According to at least one embodiment the recess comprises at least one of a hole and a partial groove. For example, at least one hole is introduced in the first conversion layer, that can in particular be an inorganic conversion layer, and the at least one hole can be filled with the matrix material in which the second phosphor is embedded forming the second conversion region. In another example, the first conversion region can be formed as a first conversion layer, in particular an inorganic first conversion layer, and at least one partial groove is cut into the first conversion layer, for example mechanically or by laser dicing. The at least one groove is filled then with matrix material in which the second phosphor is embedded forming the second conversion region. A shape, a depths and a widths of the at least one groove can vary. When more than one groove are present, they can be in a linear pattern, a cross-hatch pattern, or in any other arrangement. If more than one recess is present in the first conversion layer, the second conversion region does not necessarily be one-piece but can be arranged separately in portions in the multiple recesses.

According to at least one embodiment the first conversion region comprises a multiplicity of loose portions which are embedded in the second conversion region. In particular the first conversion region is an inorganic first conversion region comprising loose portions, the loose portions comprising crushed ceramic pieces, for example. The loose portions can be smaller than a thickness of a typical ceramic converter element but larger than a typical phosphor particle. The loose portions can be included in the matrix material of the second conversion region along with the second phosphor and any other additives.

According to at least one embodiment the first conversion region and/or the second conversion region comprise structured surfaces. “Surfaces” are in this context exposed surfaces, thus, outer surfaces of the converter element. Such surfaces face an excitation source, for example a semiconductor chip, or face away from the excitation source. Structured surfaces can improve and/or adapt radiation in-coupling and radiation out-coupling characteristics. Structured surfaces are according to at least one embodiment chosen from a group consisting of random roughness, microoptics like microlenses, photonic crystals, plasmonic arrays, meta lenses, aperiodic nanostructured arrays, dielectric films, stacks of dielectric films like anti-reflective coatings, dichroic filters, or wavelength/angle-dependent pass filters, and graded index anti-reflective coatings.

According to at least one embodiment the converter element comprises a thickness of up to 500 μm. In particular, the converter element comprises a thickness in a range of 30 μm to 300 μm inclusive, for example 80 μm to 120 μm inclusive, for example 100 μm. Due to the matrix material contained in at least one of the conversion regions thicknesses of these conversion regions of greater than 10 to 25 μm can be realized without cracking. If present, an inorganic conversion region makes up between 20% and 95% of the total thickness of the converter element.

According to at least one embodiment the converter element comprises a lateral dimension in a range of up to several millimetres. Thus, the converter element can be formed in a lateral size that is appropriate for any desired application. Typical applications require lateral dimensions in the order of a few millimetres, but larger sizes and smaller sizes, for example sub-millimetre sizes are also possible.

According to at least one embodiment the conversion element comprises at least one additional conversion region. The additional conversion region(s) comprises the matrix material and an additional phosphor embedded therein. The additional phosphor(s) of the additional conversion region(s) can be chosen such that with increasing distance from the first conversion region and, thus, the first phosphor, the radiation decay lifetime of the additional phosphor(s) increases, i.e. becomes slower. In particular, the first phosphor, the second phosphor and the additional phosphor(s) are different from each other.

Further, a method for producing a converter element is provided. The method is suitable for producing a converter element as described here. Thus, all features and embodiments described with respect to the converter element are also valid for the method and vice versa.

According to at least one embodiment the method comprises the steps:
preparing a first conversion region comprising a first phosphor,
preparing a second conversion region comprising a second phosphor, and
combining the first and the second conversion region,
wherein the first phosphor has upon excitation a faster radiation decay lifetime than the second phosphor,
wherein at least one of the first and the second conversion region is prepared by providing a polysiloxane precursor,
embedding the first or the second phosphor in the polysiloxane precursor to create a mixture, curing the mixture, wherein a matrix material comprising a three-dimensionally crosslinked polysiloxane having an organic content of less than 40 wt % and the first or the second phosphor being embedded therein is produced.

The steps preparing the first conversion region, preparing the second conversion region and combining the first and the second conversion region can be conducted consecutively or simultaneously.

Either the first conversion region or the second conversion region or both are produced by providing the polysiloxane precursor and embedding the respective, i.e. the first or the second phosphor. Thus, the method produces a converter element that has a first conversion region comprising the matrix material and the first phosphor embedded therein and/or a second conversion region comprising the matrix material and the second phosphor embedded therein.

A polysiloxane precursor is in this context an uncured siloxane resin which in particular is liquid or solution-based. When providing the polysiloxane precursor, additives such as thickeners or fillers can be additionally added. For example microparticles and/or nanoparticles can be added to the polysiloxane precursor in order to change a property such as the viscosity of the mixture in the uncured state or the refractive index, the thermal conductivity or the mechanical hardness in the cured state, i.e. of the three-dimensionally crosslinked polysiloxane. Additives can be chosen from fumed silica, SiO₂, ZrO₂, TiO₂, Al₂O₃ or ZnO. The mixture comprising the polysiloxane precursor, the phosphor and optionally additives can also be called a slurry.

According to at least one embodiment a catalyst or hardener is added to the mixture. A catalyst is able to support the curing reactions. In particular, a catalyst is added to the mixture shortly before the mixture is applied on the position, for example a surface, where it is allowed to cure. A catalyst or hardener can be added in a small amount, i.e. 0.05 wt % to 5 wt % with respect to the polysiloxane precursor. Examples for hardeners or catalysts are, in particular, titanium alkoxides, amine-containing bases, or combinations thereof.

According to at least one embodiment the phosphor is embedded in the polysiloxane precursor in an amount in the range of 8 vol % to 74 vol % inclusive, in particular in a range of 15 vol % to 55 vol % inclusive.

According to at least one embodiment the polysiloxane precursor comprises repeating units of the formula [(R)(OR)SiO]ₓ[R₂SiO]_{y}[R₃SiO_{1/2}]_{z} wherein x+y+z=1, 0<x≤1, 0≤y<1, 0≤z<1; preferably 0.6≤x≤1, 0≤y<0.4, 0≤z<0.4, and each R is independently from each other chosen from an organic functional group having a carbon atom as bonding atom, in particular from methyl and phenyl, wherein an alkoxy content is in a range of 10 wt % to 50 wt %, in particular in a range of 15 wt % to 45 wt %, for example in a range of 30 wt % to 40 wt %, and/or wherein the precursor comprises a number of repeating units such that a viscosity of the precursor is less than 150 mPas, in particular less than 40 mPas. Here, x, y, and z indicate the relative proportions of the three types of groups, T-, D- and M-units, respectively. In particular, the relative proportion of T-units is higher than the relative proportions of D- and M-units. For example, the polysiloxane precursor comprises more than 60% T-units, in particular 100% T-units. The formula can also be described by bond-line formula (II)

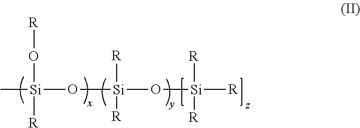

In formula (II) the curved brackets indicate repeating units, while the square bracket do not necessarily indicate repeating units.

According to at least one embodiment R is methyl and y=z=0. In this case the precursor is methyl methoxy siloxane being only based on T-units and comprising a repeating unit of the formula (CH₃)(OCH₃)SiO, that can also be described by the bond-line formula (IIa)

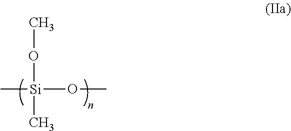

Here, n is the number of repeating units and n<75, preferably n<50, even more preferably, n<10.

According to at least one embodiment preparing the first conversion region and preparing the second conversion region are successively conducted. For example, the first conversion region is prepared by providing the polysiloxane precursor, embedding the first phosphor and curing the resulting mixture. Subsequently, the mixture of polysiloxane precursor and second phosphor is applied on the first conversion region and allowed to cure. In an alternative example, an inorganic first conversion region is produced. For example, a ceramic first conversion region of green- and/or yellow emitting material from the A₃B₅O₁₂ garnet system with A some combination of Ce, Y, Lu, Gd, Tb where Ce is necessary and makes up from 0.001% to 10% of the A atoms and B is some combination of Al, Ga and Sc is produced. Subsequently, a mixture containing the polysiloxane precursor and the second phosphor is applied on the inorganic first conversion region and allowed to cure so a stable solid second conversion region is attached to the inorganic first conversion region, both forming a single hybrid converter element.

Alternatively, the second conversion region can be produced separately, for example on a substrate, and glued to the first conversion region. In a further example, the first conversion region can be produced and structured by producing at least one hole or at least one partial recess in the first conversion region, in particular an inorganic first conversion region. Subsequently, the mixture of polysiloxane precursor and second phosphor is applied to the hole or the partial recess and allowed to cure. In a further example, the first conversion region can be produced as an inorganic conversion region and crushed into loose portions. Subsequently, the loose portions are embedded into the mixture containing the polysiloxane precursor and the second phosphor. Afterwards, the mixture is allowed to cure. Independently of the concrete example, the converter element can be produced as a large wafer that is diced after its production, or the converter element can be produced already shaped into its final size.

According to at least one embodiment combining the first conversion region and the second conversion region comprises gluing. For example, first and second conversion regions can be produced separately from each other and glued together afterwards resulting in a bonding region between first conversion region and second conversion region.

According to at least one embodiment, before curing, the mixture is applied on a surface by a method chosen from spraying, tape-casting, doctor-blading, spin coating, dispensing, and casting. The surface can belong to a intermediate substrate where the respective conversion region is prepared before applying it at its final position in the converter element, or the surface can be the surface of an already prepared conversion region, for example the first conversion region.

According to at least one embodiment preparing the first conversion region comprises forming a first conversion layer and wherein preparing a second conversion region comprises forming a second conversion layer. In particular, the first conversion layer and the second conversion layer are prepared such that they are stacked.

According to at least one embodiment curing is performed in ambient conditions. According to at least one embodiment curing is performed for a time chosen from the range of 1 hour to 5 days.

Further, a radiation emitting device is provided. According to at least one embodiment the radiation emitting device comprises a semiconductor chip which, during operation, emits electromagnetic radiation in a first wavelength range from a radiation exit surface, and a converter element as described here on the radiation exit surface converting the electromagnetic radiation of the first wavelength range into an electromagnetic radiation of a second wavelength range.

All features and embodiments disclosed with respect to the converter element and the method for producing a converter element are also valid for the radiation emitting device and vice versa.

The electromagnetic radiation of the first wavelength range may also be called primary radiation and corresponds to the emission spectrum of the semiconductor chip. According to at least one embodiment the primary radiation comprises wavelengths from the UV range and/or from the visible range, in particular from the blue range. For example, the primary radiation comprises wavelengths in the range of 400 nm to 500 nm with a wavelengths maximum at, for example, 450 nm.

The semiconductor chip may be a light emitting diode chip or a laser diode chip. According to at least one embodiment the light emitting device is a light emitting diode (LED). In particular, the semiconductor chip comprises an epitaxial grown semiconductor layer sequence with an active region being able to generate electromagnetic radiation. For example the active region comprises a pn-junction or a quantum well structure.

The converter element is applied on the radiation exit surface of the semiconductor chip such that light emitted from the semiconductor chip reaches at least partially the converter element. The phosphors being contained in the converter element convert the electromagnetic radiation of the first wavelength range into electromagnetic radiation of a second wavelength range, also called secondary radiation. The electromagnetic radiation of the second wavelength range corresponds to the total emission spectrum of all phosphors. In particular, the first wavelength range is different from the second wavelength range.

The converter element can convert the light emitted by the semiconductor chip fully. Alternatively, the converter element can convert the light emitted by the semiconductor chip partially while another part is transmitted, such that the device emits a mixed light comprising primary and secondary radiation. Due to the matrix material contained in the converter element the converter element has an improved thermal stability and thermal conductivity and, thus, the radiation emitting device can be operated with high radiation fluxes and high operating temperatures such as 150° C. or more without degradation. At the same time an arbitrary number of distinct phosphor compositions can be accommodated in the converter element as described here and, thus, a desired spectral range of emitted light can be realized.

According to at least one embodiment the first conversion region of the converter element is closer to the semiconductor chip than the second conversion region. For example, the first conversion region is in direct mechanical contact with the semiconductor chip or is glued to the semiconductor chip while the second conversion region is on a side of the converter element facing away from the semiconductor chip. In particular, the first and second conversion regions are first and second conversion layers and the first conversion layer is in direct or indirect contact to the semiconductor chip while the second conversion layer is on the side of the converter element facing away from the semiconductor chip. Thus, the first phosphor having a faster radiation decay lifetime upon excitation is nearer to the semiconductor chip and so saturation of the second phosphor is reduced or eliminated.

For example, the first conversion region comprises a first phosphor being a ceramic, a single crystal or a phosphor-in-glass. For example, the first phosphor is a ceramic Ce-doped phosphor that can sustain higher fluxes and also helps dissipating heat. The second conversion region in this case comprises the matrix material as described here, with the second phosphor being embedded therein. For example, the second phosphor is a Eu-doped phosphor having a slower radiation decay lifetime than the first phosphor.

According to at least one embodiment the converter element is glued to the semiconductor chip or wherein the converter element is applied in a remote configuration to the semiconductor chip. For gluing the converter element to the semiconductor chip any type of silicone, filled silicone, siloxane, or filled siloxane can be used. For example, the matrix material can be used as a glue. In a remote configuration there is a certain distance between the converter element and the semiconductor chip and the converter element can be pumped by the chip. Independently of the configuration, the converter element is in particular arranged such that the first conversion region is closer to the semiconductor chip than the second conversion region.

Advantageous embodiments and developments of the converter element, the method for producing the converter element, and the radiation emitting device will become apparent from the exemplary embodiments described below in conjunction with the figures.

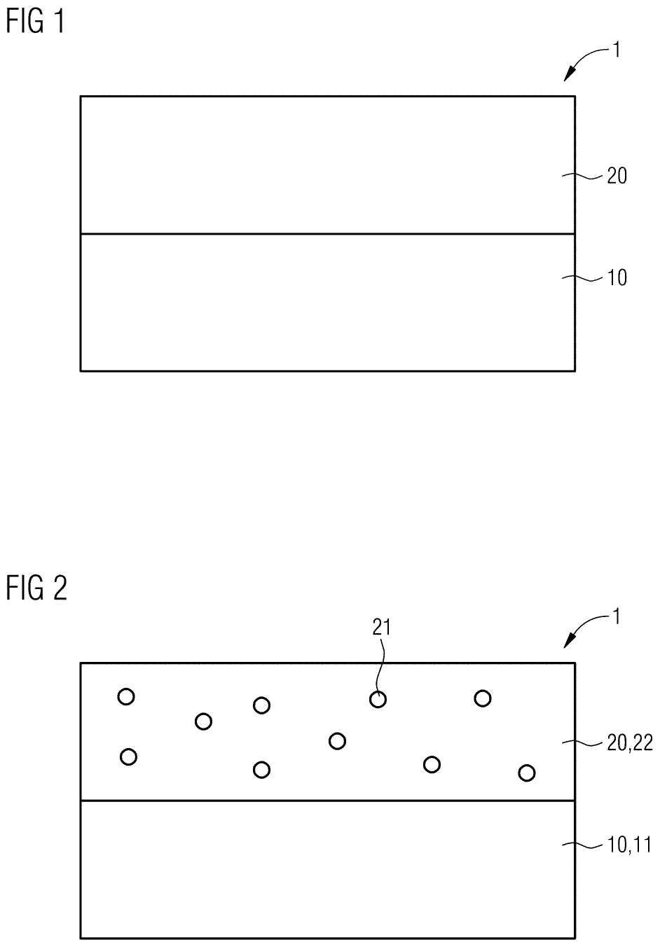

FIGS. 1 to 6 show schematic cross sectional views of converter elements according to various embodiments.

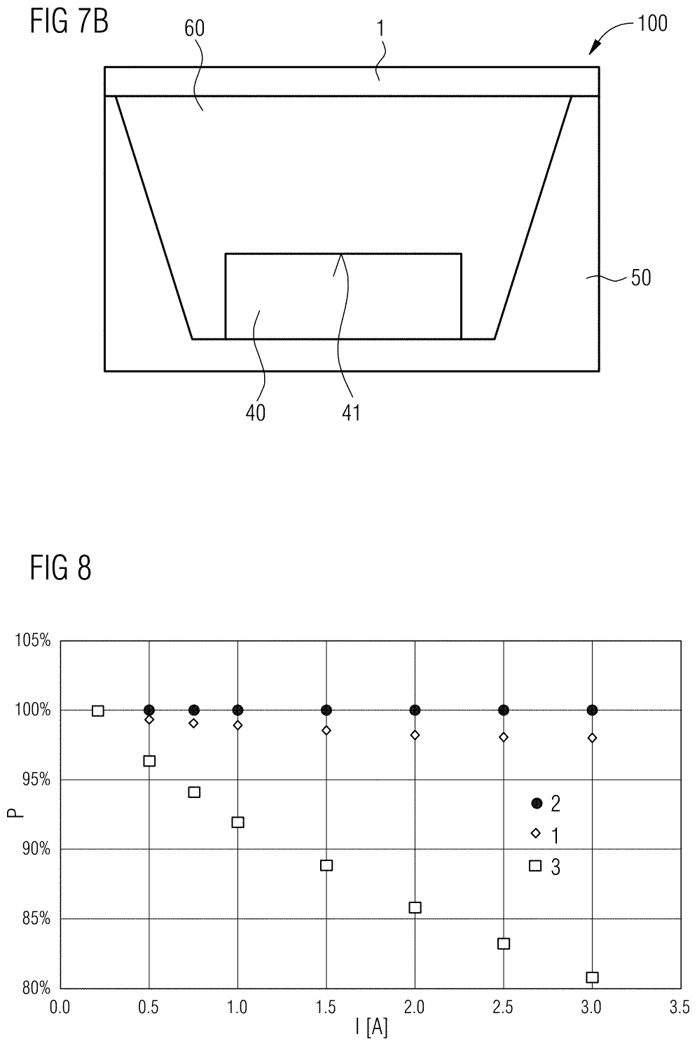

FIGS. 7a and 7b show schematic cross sectional views of radiation emitting devices according to various embodiments.

FIG. 8 shows the relative power loss of an exemplary embodiment and reference examples.

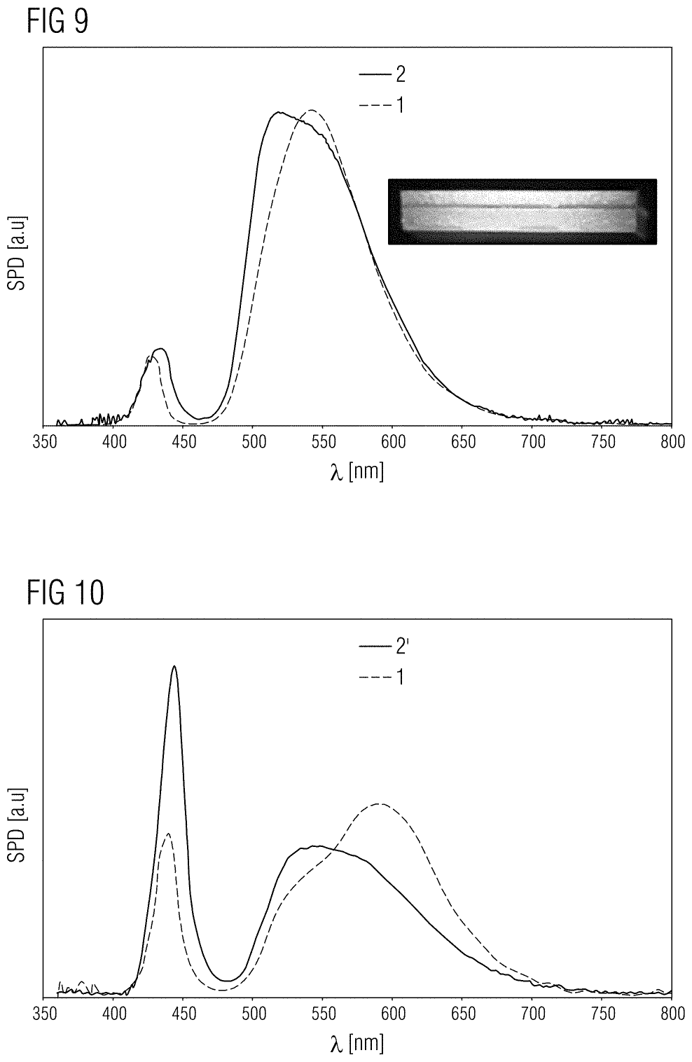

FIG. 9 shows a spectral power distribution of an exemplary embodiment and a reference example.

FIG. 10 shows a spectral power distribution of an exemplary embodiment and a reference example.

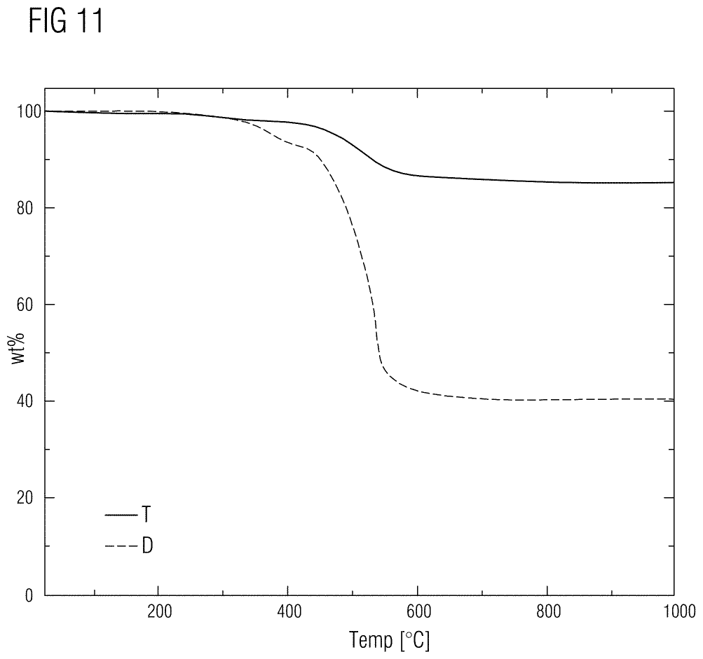

FIG. 11 shows thermogravimetric analysis profiles of an exemplary embodiment and a reference example.

In the exemplary embodiments and figures, similar or similarly acting constituent parts are provided with the same reference symbols. The elements illustrated in the figures and their size relationships among one another should not be regarded as being true to scale. Rather, individual elements may be represented with an exaggerated size for the sake of better representability and/or for the sake of better understanding.

FIG. 1 shows a schematic cross sectional view of a converter element 1 containing a first conversion region 10 and a second conversion region 20. In this exemplary embodiment both conversion regions 10 and 20 are formed as layers that are stacked. At least one of the conversion regions 10, 20 comprises a matrix material being a three-dimensionally crosslinked polysiloxane and a phosphor embedded therein. One of the conversion regions 10 and 20 can be an inorganic conversion region being formed of a ceramic phosphor, a single crystal phosphor or a phosphor-in glass.

In the following the first conversion region 10 will be described as an inorganic first conversion region 10 comprising a ceramic first phosphor 11, and the second conversion region 20 will be described as containing a second phosphor 21 being embedded in the matrix material 22. However, this is not to be understood as limiting. Rather, even both conversion regions 10, 20 can comprise the matrix material 22 with an embedded phosphor or the second conversion region 20 can comprise a ceramic phosphor while the first conversion region 10 comprises the matrix material 22 with an embedded first phosphor 11. Independently of the composition of the conversion regions 10 and 20, the first phosphor 11 in the first conversion region 10 has a faster radiation decay lifetime upon excitation than the second phosphor 21 contained in the second conversion region 20.

FIG. 2 shows the converter element 1 of FIG. 1 in more detail. First conversion region 10 is formed of the first phosphor 11, which is in this exemplary embodiment a ceramic phosphor, for example a Ce-doped ceramic phosphor which has a one or to orders of magnitude faster radiation decay lifetime than an Eu-doped phosphor. Second conversion region 20 comprises the matrix material 22 in which the second phosphor 21, for example an Eu-doped phosphor, is embedded. The second phosphor 21 is a phosphor powder comprising particles, which are embedded in the matrix material 22. The second phosphor 21 could also be a blend of different phosphors, all having a slower radiation decay lifetime than the first phosphor 11. For example, the second phosphor 21 is an Eu-doped phosphor which provides a high spectral flexibility of the converter element 1. The converter element 1 is a hybrid converter element.

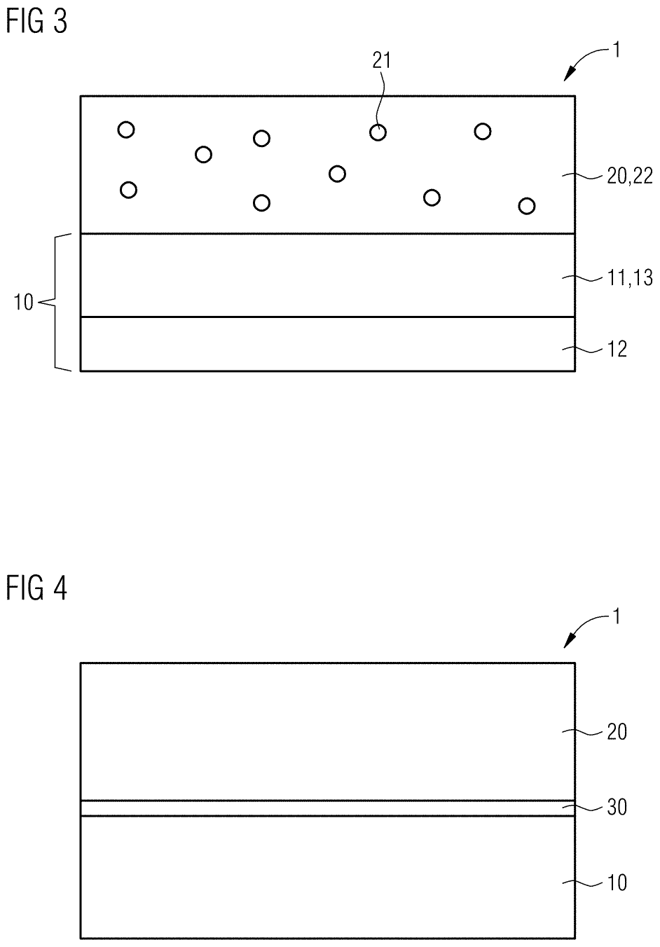

FIG. 3 shows a schematic cross sectional view of another exemplary embodiment of the converter element 1. While second conversion region 20 corresponds to second conversion region 20 of FIG. 2, first conversion region 10 is formed of a composite material with a luminescent second phase 13 being formed of the ceramic first phosphor 11, for example a Ce-doped phosphor, and a non-luminescent first phase 12, both phases being a dense sintered body. The non-luminescent phase 12 comprises silica, alumina, or any oxide garnet, spinel, or silicate. Any other inorganic material that has a relatively high thermal conductivity but low absorption in the visible region of the spectrum can be chosen as well.

FIG. 4 shows a schematic cross sectional view of another exemplary embodiment. In contrast to the FIGS. 1 to 3, where first and second conversion regions 10, 20 are in direct mechanical contact, here, the first conversion region 10 and the second conversion region 20 are glued to each other. Thus, bonding layer 30 is between the first and second conversion regions 10 and 20. The bonding layer 30 comprises or consists of a glue like silicone, filled silicone, siloxane, or filled siloxane.

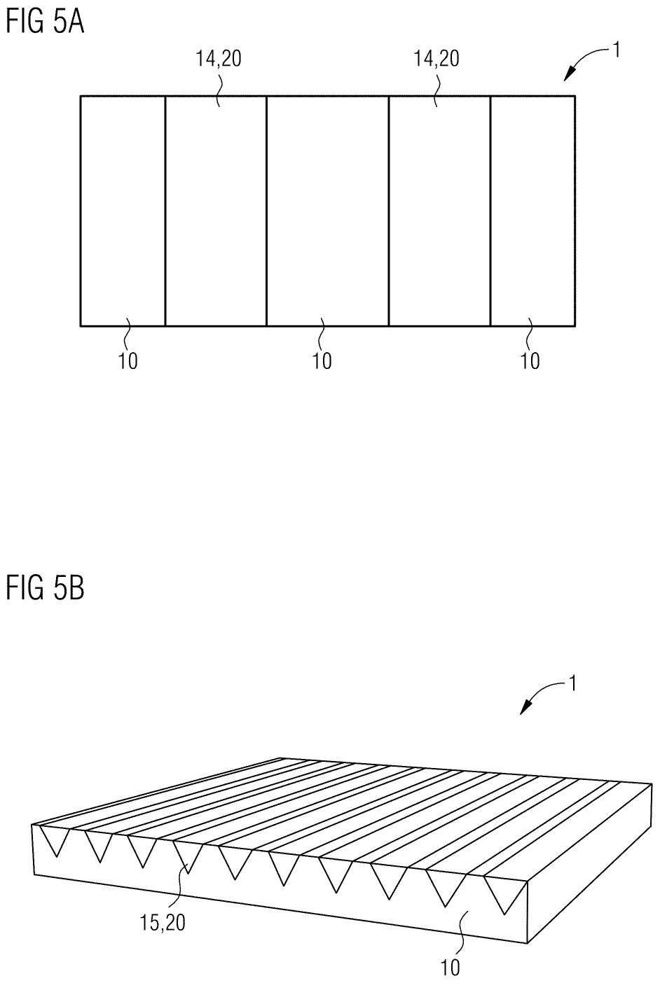

In FIGS. 1 to 4 the first and the second conversion regions 10, 20 are formed as layers. FIGS. 5a and 5b show exemplary embodiments where the first conversion region 10 is formed as a layer but comprises structures, and the second conversion region 20 is arranged in the structures. According to FIG. 5a the first conversion region 10 comprises two holes 14 ranging from one surface of the first conversion region 10 to the opposite surface of the first conversion region 10. The second conversion region 20 is arranged in the holes 14 so that one compact converter element 1 is formed. According to FIG. 5b partial grooves 15 are formed in the first conversion region 10 and the second conversion region 20 is arranged in the partial grooves 15. Thus, the second conversion region 20 is not necessarily continuously formed in one piece.

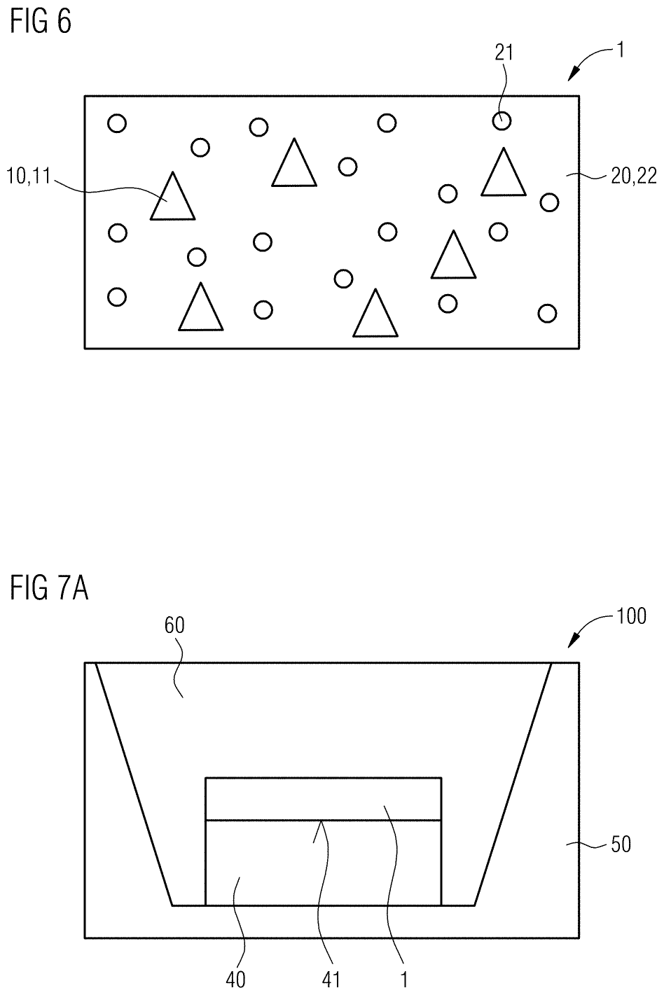

FIG. 6 shows a cross sectional view of another exemplary embodiment. Here, second conversion layer 20 is formed as a layer and comprises the matrix material 22 and the second phosphor 21. Additionally, it comprises loose portions of first conversion regions 10 being in this example formed of the ceramic first phosphor 11. The loose portions are larger than the phosphor particles 21 but smaller than a non-crushed first conversion region 10.

In the following the production of an exemplary embodiment of a converter element 1 is explained. In this example the converter element 1 is formed for using it in high CRI (color rendering index) warm-white applications.

As first conversion region 10 a layer of the ceramic phosphor 11 of (Lu₁₋ₓCeₓ)₃(Al_{1-y}Ga_{y})₅O₁₂ where 0<x≤0.1 and 0≤y≤1 is made according to any known method for making ceramic layers of such a material. For the second conversion region 20 a second phosphor powder 21 of (Sr_{y}Ca_{1-x-y}Euₓ)AlSiN₃ where 0<x≤0.1 and 0≤y≤1-x is provided. For producing the matrix material 22, a polysiloxane precursor, in this example methyl methoxy polysiloxane with a methoxy content between 10% and 50%, preferably between 30% and 40%, is provided and mixed with the second phosphor 21. Before curing this mixture, fumed silica may be added in a range of up to 30 wt % with respect to the total precursor material. The precursor material should be chosen such that it comprises more than 85%, more preferably 100% T-unit type functional monomers. The second phosphor powder 21, the methyl methoxy polysiloxane, and optionally fumed silica are thoroughly mixed together, and a small amount of catalyst or hardener, i.e. 0.05 to 5 wt % with respect to the precursor material, is added. A wide range of hardeners can be applied, in particular titanium alkoxides, amine-containing bases, or combinations thereof.

The so prepared mixture is applied to one surface of the ceramic first conversion region 10 by spraying, or some other suitable method such as tape-casting, doctor blading, spin coating, casting, or dispensing. The applied mixture is allowed to cure in ambient conditions for several hours up to several days, before the second conversion region 20 and, thus, the converter element 1, is finished. The converter element 1 can in a further step incorporated into a radiation emitting device.

The total thickness of the converter element 1 should be between 30 μm to 500 μm inclusive, for example 30 μm and 300 μm inclusive, in particular the thickness should be less than 200 μm. The ceramic first conversion region 10 should make up between 20% and 95% of the total thickness of the converter element 1, in particular between 50% and 90%.

The converter element 1 is incorporated in a radiation emitting device 100, in particular it is arranged on a radiation exit surface of a semiconductor chip 40 of the device. To reduce saturation and optimize thermal management, the ceramic first conversion region 10 should be the region or layer being closer to the semiconductor chip 40 so that the first phosphor 11 having the faster radiation decay lifetime is closer to the semiconductor chip 40 than the second phosphor 21. The ceramic first conversion region 10, in particular if made of Ce-doped materials, can sustain higher fluxes and also helps dissipate heat.

The exemplary embodiment of the method for producing the converter element 1 is suitable to produce the converter element 1 as shown in FIG. 1 or 2, for example. Upon slight modifications of the method any other converter element as shown in 3 to 6 can be produced similarly.

Further, various other materials can be used for the production of the converter element 1. As first or second phosphor one or more phosphors as listed above can be chosen. Instead of a ceramic the first phosphor can be a single crystal phosphor or a phosphor-in-glass. The polysiloxane precursor does not necessarily have methyl side groups, but any combination of alkyl and aryl groups are possible as well, as long as the alkoxy content ranges from 10 wt % to 50 wt % in order to get a matrix material 22 having less than 40 wt %, preferably less than 20 wt % organic content. Further the number of siloxane monomer units of the polysiloxane precursor should be in a range such that the viscosity is less than 150 mPas, preferably less than 40 mPas.

Further, additives may be added to the precursor material in order to change a property such as the viscosity of the mixture or the refractive index, the thermal conductivity or the mechanical hardness of the cured matrix material 22.

FIGS. 7a and 7b show schematic cross sectional views of radiation emitting devices 100 according to exemplary embodiments. Both figures show a housing 50 with a recess in which a semiconductor chip 40 is arranged. In FIG. 7a the converter element 1 is directly arranged on the semiconductor chip 40 and, thus, on the radiation exit surface 41. Converter element 1 and chip 40 are optionally surrounded by a encapsulant 60, being a transmissive, non-absorbing material, that even fills the recess. FIG. 7b shows a remote configuration where converter element 1 is arranged on top of the housing 50 and optionally the encapsulant 60 and, thus, with a certain distance to the semiconductor chip 40 and the radiation exit surface 41. The semiconductor chip 40 is according to an example a blue emitting LED chip. Any converter element 1 as described with respect to FIGS. 1 to 6 can be applied to the radiation emitting device 100.

Independently of the configuration of the radiation emitting device 100, the converter element 1 should be applied to the semiconductor chip 40 and the radiation exit surface 41 such that the first conversion region 10 is closer to the chip 40 than the second conversion region 20. Thus, saturation of the second phosphor 21 can be reduced and the thermal management through the converter element 1 can be optimized.

FIG. 8 shows the relative power loss P of a known Ce-doped ceramic Ce:LuAG 2 (solid circle), an Eu-doped phosphor Eu:β-SiAlON 3 in the matrix material (hollow squares) and a hybrid converter element 1 (hollow diamonds) combining the Ce-doped ceramic in a first conversion region 10 and the Eu-doped phosphor in a second conversion region 20. Current I in A versus the power loss P relative to the ceramic 2 is shown. It can be observed that despite the converter element 1 contains an Eu-doped phosphor having a slow radiation decay lifetime, the loss at high currents I is just 2% higher than in the pure ceramic 2. Compared to this the Eu-doped phosphor in matrix material drops its emission 19% to 20% at about 3 A due to saturation losses. This shows that saturation can be reduced by combining the second conversion region 20 with a ceramic first conversion region 10 and by choosing a phosphor with fast radiation decay lifetime as the first phosphor being closer to the excitation source, i.e. the semiconductor chip 40.

FIG. 9 shows spectra of the ceramic 2 and the converter element 1 of FIG. 8. Wavelength λ in nm versus spectral power distribution SPD in a.u. is shown. The inset shows an optical image of a cross section of the converter element 1 which is 1.5 mm wide and 250 μm thick. The first and second conversion regions 10,20 are separated by bonding layer 30 between them. By adding more or less of each material the spectra of the converter element 1 and of the ceramic 2 can be tuned to be narrower and thus increase the lumen equivalent value.

FIG. 10 shows the spectral power distribution SPD in a.u. in dependence of wavelength λ in nm for a ceramic phosphor 2′ which is Ce:YAG emitting cold white light and for a converter element 1 comprising in this example an Eu-doped red-emitting nitride and the matrix material. By using such a converter element 1 it is possible to obtain a device that emits a warmer white (lower CCT, correlated color temperature) while keeping the Ce-doped material close to the excitation source, i.e. the semiconductor chip 40, and thus reducing the effects of saturation. This example shows, that by combining different phosphors in the converter element 1 a high spectral flexibility can be realized while saturation can be reduced.

FIG. 11 shows thermogravimetric analysis profiles of a cured methyl-based silicone reference D (based on D-units) along with a cured methyl-based polysiloxane T (based on T-units) as used for the here described matrix material. The reference D was cured using the vendors recommended method, and the example T was likewise cured according to the recommended method. Each sample was analyzed by thermogravimetric analysis (TGA) the plots of which are shown in FIG. 11, showing the wt % in dependence of temperature Temp in ° C. The reference sample D lost about 60% of its mass, which corresponds to its organic content. The example T, i.e. the here described matrix material, lost less than 20% of its mass indicating a significantly lower organic content. This large difference in organic content is an important factor as to why the reference sample is not suitable for use in high temperature applications, but the here described matrix material is more thermally stable.

The features and exemplary embodiments described in connection with the figures can be combined with each other according to further exemplary embodiments, even if not all combinations are explicitly described. Furthermore, the exemplary embodiments described in connection with the figures may have alternative or additional features as described in the general part.

The invention is not restricted to the exemplary embodiments by the description on the basis of said exemplary embodiments. Rather, the invention encompasses any new feature and also any combination of features, which in particular comprises any combination of features in the patent claims and any combination of features in the exemplary embodiments, even if this feature or this combination itself is not explicitly specified in the patent claims or exemplary embodiments.

### REFERENCES

1 converter element

2 Ce:LuAG ceramic

2′ Ce:YAG ceramic

3 Eu:β-SiAlON in matrix material

10 first conversion region

11 first phosphor

12 first phase

13 second phase

14 hole

15 partial groove

20 second conversion region

21 second phosphor

22 matrix material

30 bonding layer

40 semiconductor chip

41 radiation exit surface

50 housing

60 encapsulant

100 radiation emitting device

I current

P power loss

λ wavelength

SPD spectral power distribution

Temp temperature

wt % weight percent

T T-unit based example

D D-unit based reference

1. A converter element, comprising:
a first conversion region comprising a first phosphor,
a second conversion region comprising a second phosphor,
wherein the first phosphor has upon excitation a faster radiation decay lifetime than the second phosphor,
wherein at least one of the first and second phosphor is embedded in a matrix material,
wherein the matrix material comprises a three-dimensionally crosslinked polysiloxane having an organic content of less than 40 wt %.

2. The converter element according to claim 1, wherein the three-dimensionally crosslinked polysiloxane comprises repeating units of the formula [RSiO_{3/2}]ₓ[R₂SiO]_{y}[R₃SiO_{1/2}]_{z} wherein x+y+z=1, 0<x≤1, 0≤y<1, 0≤z<1, and each R is independently from each other chosen from an organic functional group having a carbon atom as bonding atom.

3. The converter element according to claim 1, wherein one of the first and the second phosphor is embedded in the matrix material and wherein the other one of the first and the second phosphor is one of a ceramic phosphor, a single crystal phosphor and a phosphor-in-glass.

4. The converter element according to claim 1, wherein the second phosphor is embedded in the matrix material and the first phosphor is one of a ceramic phosphor, a single crystal phosphor and a phosphor-in-glass.

5. The converter element according to claim 1, wherein the first conversion region and/or the second conversion region comprises a first phase being free of phosphor and a second phase comprising the phosphor.

6. The converter element according to claim 1, wherein the first conversion region and the second conversion region comprise a common boundary or wherein the first conversion region and the second conversion region are glued together.

7. The converter element according to claim 1, wherein the first conversion region is a first conversion layer and the second conversion region is a second conversion layer, wherein the first and second conversion layers are stacked.

8. The converter element according to claim 1, wherein the first conversion region is a first conversion layer comprising at least one recess, wherein the second conversion region is arranged in the at least one recess.

9. The converter element according to claim 8, wherein the recess comprises at least one of a hole and a partial groove.

10. The converter element according to claim 1, wherein the first conversion region comprises a multiplicity of loose portions which are embedded in the second conversion region.

11. The converter element according to claim 1, wherein the first conversion region and/or the second conversion region comprise structured surfaces.

12. A method for producing a converter element comprising the steps of:
preparing a first conversion region comprising a first phosphor,
preparing a second conversion region comprising a second phosphor, and
combining the first and the second conversion region,
wherein the first phosphor has upon excitation a faster radiation decay lifetime than the second phosphor,
wherein at least one of the first and the second conversion region is prepared by providing a polysiloxane precursor,
embedding the first or the second phosphor in the polysiloxane precursor to create a mixture, curing the mixture, wherein a matrix material comprising a three-dimensionally crosslinked polysiloxane having an organic content of less than 40 wt % and the first or the second phosphor being embedded therein is produced.

13. The method according to claim 12, wherein the polysiloxane precursor comprises repeating units of the formula [(R)(OR)SiO]ₓ[R₂SiO]_{y}[R₃SiO_{1/2}]_{z}
wherein x+y+z=1, 0<x≤1, 0≤y<1, 0≤z<1, and
each R is independently from each other chosen from an organic functional group having a carbon atom as bonding atom,
wherein an alkoxy content is in a range of 10 wt % to 50 wt % and/or wherein the precursor comprises a number of repeating units such that a viscosity of the precursor is less than 150 mPas.

14. The method according to claim 12, wherein preparing the first conversion region and preparing the second conversion region are successively conducted.

15. The method according to claim 14, wherein combining the first conversion region and the second conversion region comprises gluing.

16. The method according to claim 12, wherein before curing the mixture is applied on a surface by a method chosen from spraying, tape-casting, doctor-blading, spin coating, dispensing, and casting.

17. The method according to claim 12, wherein preparing the first conversion region comprises forming a first conversion layer and wherein preparing a second conversion region comprises forming a second conversion layer.

18. A radiation emitting device, comprising:
a semiconductor chip which, during operation, emits electromagnetic radiation in a first wavelength range from a radiation exit surface, and a converter element according to claim 1 on the radiation exit surface converting the electromagnetic radiation of the first wavelength range into an electromagnetic radiation of a second wavelength range.

19. The radiation emitting device according to claim 18, wherein the first conversion region of the converter element is closer to the semiconductor chip than the second conversion region.

20. The radiation emitting device according to claim 18, wherein the converter element is glued to the semiconductor chip or wherein the converter element is applied in a remote configuration to the semiconductor chip.
